(19) United States
(12) Patent Application Publication
(10) Pub. No.: US 2018/0175187 A1
(43) Pub. Date: Jun. 21, 2018

(54) Semiconductor Device Comprising a Plurality of Transistor Cells and Manufacturing Method

(71) Applicant: Infineon Technologies Austria AG, Villach (AT)

(72) Inventor: Franz Hirler, Isen (DE)

(21) Appl. No.: 15/886,305

(22) Filed: Feb. 1, 2018

Related U.S. Application Data
(63) Continuation of application No. 14/790,665, filed on Jul. 2, 2015, now abandoned.

(30) Foreign Application Priority Data
Jul. 15, 2014 (DE) 102014109926.5

(51) Int. Cl. H01L 29/78; H01L 29/66; H01L 29/423; H01L 29/06; H01L 29/40; H01L 29/10; H01L 29/08

(52) U.S. Cl. CPC H01L 29/7802; H01L 29/7813; H01L 29/66734; H01L 29/42364; H01L 29/4236; H01L 29/407; H01L 29/404; H01L 29/1095; H01L 29/0878; H01L 29/0696; H01L 29/0623

(57) ABSTRACT

A semiconductor device comprises a plurality of transistor cells. Each one of the plurality of transistor cells comprises a trench extending into a drift zone of a semiconductor body from a first surface, the drift zone being of a first conductivity type. The semiconductor device further comprises a gate electrode structure. A field electrode structure and a first dielectric structure are in the trench. A doped region is embedded in the drift zone lining a bottom side of the trench. The doped region is one of a first conductivity type having a doping concentration lower than the drift zone, and a second conductivity type complementary to the first conductivity type.

### BACKGROUND

Semiconductor devices such as insulated gate field effect transistors (IGFETs), for example metal oxide semiconductor field effect transistors (MOSFETs) are widely used for semiconductor applications. Many applications require semiconductor devices having low output capacitance. In switched-mode power supply devices such as resonant half bridge (LLC) converters, rectifying elements enabling low output capacitance are desired for avoiding drawbacks in light load or no load operation.

### SUMMARY

According to an embodiment of a semiconductor device, the semiconductor device comprises a plurality of transistor cells. Each transistor cell comprises a trench extending into a drift zone of a semiconductor body from a first surface, the drift zone being of a first conductivity type. The semiconductor device further comprises a gate electrode structure. The semiconductor device further comprises a field electrode structure and a first dielectric structure in the trench. A doped region of the semiconductor structure is surrounded by the drift zone and lines a bottom side of the trench. The doped region is of a first conductivity type having a doping concentration lower than the drift zone. The first dielectric structure includes a field dielectric part between each one of opposite sidewalls of the trench and the field electrode structure, and a gate dielectric part between each one of opposite sidewalls of the trench and the gate electrode structure. A thickness of the gate dielectric part is smaller than a thickness of the field dielectric part.

According to another embodiment of a semiconductor device, the semiconductor device comprises a plurality of transistor cells. Each transistor cell comprises a trench extending into a drift zone of a semiconductor body from a first surface, the drift zone being of a first conductivity type. The semiconductor device further comprises a gate electrode structure. The semiconductor device further comprises a field electrode structure and a first dielectric structure in the trench. The first dielectric structure in the trench includes a first part between each one of opposite sidewalls of the trench and the field electrode structure, a second part between a bottom side of the trench and the field electrode structure, and a third part between each one of opposite sidewalls of the trench and the gate electrode structure, the first part having a first thickness d₁ in a direction parallel to the first surface, the second part having a second thickness d₂ in a direction perpendicular to the first surface, the third part having a third thickness d₃ in a direction parallel to the first surface, the first thickness being smaller than the second thickness, and the third thickness being smaller than the first thickness.

Another embodiment relates to a method for forming a semiconductor device comprising a plurality of transistor cells. Forming each transistor cell comprises forming a trench extending into a drift zone of a semiconductor body from a first surface, the drift zone being of a first conductivity type. The method further comprises forming a doped region surrounded by the drift zone and lining a bottom side of the trench. The doped region is of of a first conductivity type having a doping concentration lower than the drift zone. The method further comprises forming a first dielectric structure and a field electrode structure in the trench. The method further comprises forming a gate electrode structure. The first dielectric structure includes a field dielectric part between each one of opposite sidewalls of the trench and the field electrode structure, and a gate dielectric part between each one of opposite sidewalls of the trench and the gate electrode structure, wherein a thickness of the gate dielectric part is smaller than a thickness of the field dielectric part.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the present invention and are incorporated in and constitute a part of the specification. The drawings illustrate embodiments of the present invention and together with the description serve to explain principles of the invention. Other embodiments of the invention and many of the intended advantages will be readily appreciated as they become better understood by reference to the following detailed description. The elements of the drawings are not necessarily to scale relative to each other. Like reference numerals designate corresponding similar parts.

FIGS. 1 and 2 illustrate schematic cross-sections of semiconductor devices including a doped region configured to reduce a capacitance at the bottom of a trench including a field electrode structure.

FIGS. 3 and 4 illustrate schematic cross-sections of semiconductor devices including a dielectric structure at the bottom of the trench configured to reduce the capacitance at the bottom of the trench including the field electrode structure.

FIGS. 5 and 6 illustrate schematic cross-sections of embodiments of semiconductor devices including measures for reduction of the capacitance at the bottom of a trench including the field electrode structure.

FIG. 7 illustrates a schematic process chart of one embodiment of a method for manufacturing a semiconductor device as illustrated in FIG. 1 or FIG. 2.

### DETAILED DESCRIPTION

In the following detailed description, reference is made to the accompanying drawings, which form a part hereof, and in which are shown by way of illustrations specific embodiments in which the invention may be practiced. It is to be understood that other embodiments may be utilized and structural or logical changes may be made without departing from the scope of the present invention. For example, features illustrated or described as part of one embodiment can be used in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements or manufacturing processes are designated by the same references in the different drawings if not stated otherwise.

As employed in the specification, the term “electrically coupled” is not meant to mean that the elements must be directly coupled together. Instead, intervening elements may be provided between the “electrically coupled” elements. As an example, none, part, or all of the intervening element(s) may be controllable to provide a low-ohmic connection and, at another time, a non-low-ohmic connection between the “electrically coupled” elements. The term “electrically connected” intends to describe a low-ohmic electric connection between the elements electrically connected together, e.g., a connection via a metal and/or highly doped semiconductor.

Some Figures refer to relative doping concentrations by indicating “⁻” or “⁺” next to the doping type. For example, “n⁻” means a doping concentration which is less than the doping concentration of an “n”-doping region while an “n⁺”-doping region has a larger doping concentration than the “n”-doping region. Doping regions of the same relative doping concentration may or may not have the same absolute doping concentration. For example, two different n⁺-doped regions can have different absolute doping concentrations. The same applies, for example, to an n⁻-doped and a p⁺-doped region. In the embodiments described below, a conductivity type of the illustrated semiconductor regions is denoted n-type or p-type, for example one of n⁻-type, n-type, n⁺-type, p⁻-type, p-type and p⁺-type. In each of the illustrated embodiments, the conductivity type of the illustrated semiconductor regions may be vice versa. In other words, in an alternative embodiment to any one of the embodiments described below, an illustrated p-type region may be n-type and an illustrated n-type region may be p-type.

Terms such as “first”, “second”, and the like, are used to describe various structures, elements, regions, sections, etc. and are not intended to be limiting. Like terms refer to like elements throughout the description.

The terms “having”, “containing”, “including”, “comprising” and the like are open and the terms indicate the presence of stated elements or features, but not preclude additional elements or features. The articles “a”, “an” and “the” are intended to include the plural as well as the singular, unless the context clearly indicates otherwise.

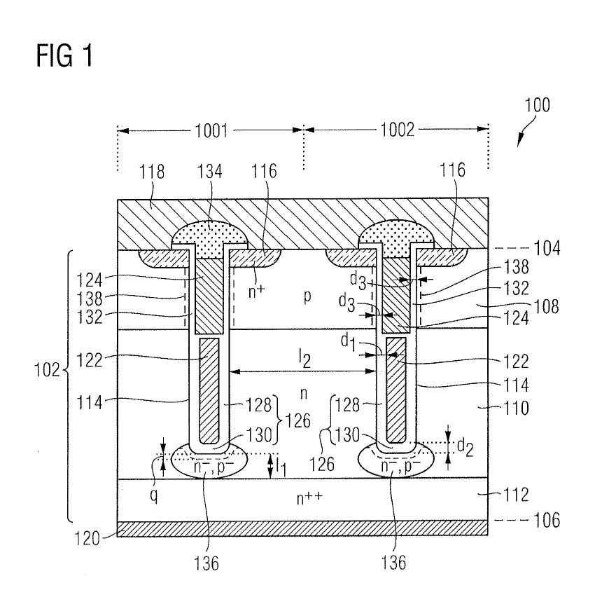

FIG. 1 illustrates a cross-section of a part of a semiconductor device 100 according to an embodiment. More specifically, FIG. 1 illustrates part of a transistor cell array of the semiconductor device 100. The transistor cell array is an active device area which comprises a plurality of transistor cells 1001, 1002, each transistor cell including a gate electrode to which a gate potential can be applied, a source zone and a body zone. The plurality of transistor cells are connected in parallel by electrically connecting their source zones with each other. A drift zone and a drain zone are common to all transistor structures in the transistor cell array. The transistor cell array is provided in a central part of the semiconductor body which adjoins an edge termination area comprising edge termination structure(s) such as field plate(s), edge termination trench(es), junction termination extension (JTE) structure(s), variation of lateral doping (VLD) structure(s) or any combination thereof.

The semiconductor device 100 includes a semiconductor body 102 with a first surface 104 and a second surface 106 opposite to the first surface 104. The semiconductor body 102 comprises a p-type body region 108, an n-type drift zone 110 and an n⁺⁺-type drain region 112. A trench 114 extends into the semiconductor body 102 from the first surface 104. The n-type drift zone 110 adjoins a lower part of the trench 114. The p-type body region 108 adjoins an upper part of the trench 114. An n⁺⁺-type source region 116 is arranged in the p-type body region 108 and adjoins the trench 114. The n⁺⁺-type source region 116 is electrically coupled to a source contact region 118 on the first surface 104. The p-type body region 108 is also electrically coupled to the source contact region 118 to which a source potential can be applied.

The n⁺⁺-type or highly doped drain region 112 is electrically coupled to a drain contact region 120 on the second surface 106. The second surface 106 may constitute a rear side of the semiconductor body 102 and the first surface 104 may constitute a front side of the semiconductor body 102. According to another embodiment, the n⁺⁺-type drain may be arranged as an up-drain at the first surface 104.

In the semiconductor device 100, the source region 116 and the drift zone 110 are doped with a dopant of a first conductivity type in this embodiment, for example arsenic (As) for an n-type doping. However, phosphorus (P), sulfur (S) and/or antimony (Sb) or any combination thereof can be used as the n-type dopant. By contrast, the body region 108 is doped with a dopant of a second conductivity type such as, for example boron (B), aluminum (Al) and/or indium (In) as p-type dopant. Depending on the dopant used for the individual regions, therefore, an n-channel or p-channel field effect transistor may be formed as the semiconductor device 100.

A field electrode structure 122 is arranged in a lower part of the trench 114 and a gate electrode structure 124 is arranged in an upper part of the trench 114. Thus, the field electrode structure 122 is arranged between the gate electrode structure 124 and a bottom side of the trench 114. Highly doped polycrystalline silicon is one example for a material of the gate electrode structure and/or the field electrode structure, but any other conductive material such as, for example, metal silicide, metal or other doped semiconductor material(s) may be used.

In the trench 114, a first dielectric structure 126 is arranged. The first dielectric structure 126 includes a first part 128 between each one of opposite sidewalls of the trench 114 and the field electrode structure 122. The first dielectric structure 126 includes a second part 130 between a bottom side of the trench 114 and the field electrode structure 122. The first part 128 and the second part 130 constitute a field dielectric. The first part 128 has a first thickness d₁ in a direction parallel to the first surface 104 and the second part 130 has a second thickness d₂ in a direction perpendicular to the first surface 104. In this embodiment, the first thickness d₁ roughly equals the second thickness d₂. In another embodiment, the second thickness d₂ is greater than the first thickness d₁, for example the second thickness d₂ is at least twice the first thickness d₁. The field dielectric, i.e. the first and second parts 128, 130 of the first dielectric structure 126, electrically isolates the field electrode structure 122 from the semiconductor body 102, i.e. from the drift zone 110.

The first dielectric structure 126 further includes a third part 132 between each one of sidewalls of the trench 116 and the gate electrode structure 124, the third part constituting a gate dielectric. The gate dielectric has a third thickness d₃ in the direction parallel to the first and second surfaces 104, 106. In this embodiment, the third thickness d₃ of the third part 132 is smaller than the first thickness d₁ of the first part 128.

Each one of the first to third parts 128, 130, 132 of the first dielectric structure 126 includes one or more electrically insulating materials such as oxide(s), nitride(s), low-k dielectric(s), for example.

The gate electrode structure 124 is electrically isolated from the source contact region 118 by an isolating structure 134.

The field electrode structure 122 and/or the gate electrode structure 124 and/or the trench 114 may be stripe-shaped. According to other embodiments, other trench or transistor cell geometries may be applied.

The field electrode structure 122 may be electrically coupled to a reference potential such as a source potential or a gate potential, for example. According to an embodiment, the field electrode structure and the gate electrode structure merge into one another.

The semiconductor device 100 further comprises a doped region 136 which is surrounded by the drift zone 110 and lines the bottom side of the trench 114. The doped region 136 may abut the trench 114 or, for example caused by segregation effects of dopants such as boron, be slightly spaced apart from the trench 114 by a distance q (see dashed line at bottom of trench 114). The doped region 136 does not extend up to that part of the sidewall of the trench 114 where the first part 128 of the first dielectric structure 126 is located. Thus, the sidewalls of the trench are in contact with the drift zone 110 and the body region 108. In an embodiment, the doped region 136 is n-type. More specifically, the doped region 136 is n⁻-type and has a lower doping concentration than the drift zone 110 between adjacent trenches 114. In another embodiment, the doped region 136 is p-type, more specifically p⁻-type. Changing of the doping type and level may be achieved by introducing acceptors into the region of the semiconductor body 102 which is located beneath the trench 114, wherein the amount of introduced acceptors defines whether the concentration of doping is merely lowered with respect to the drift zone 110 or whether counter-doping of the doping type of the drift zone 110 occurs, i.e. the conductivity type of the drift zone 110 is reversed by the introduced acceptors.

According to an embodiment, the doped region 136 has a width in a lateral direction parallel to the first surface 104 which is in a range of 0.2 μm to 2 μm. According to another embodiment, the doped region 136 has a width in the lateral direction which is the width of the mesa structure in the lateral direction parallel to the first surface 104 or less, wherein the mesa structure corresponds to the region of the semiconductor body 102 that is located between adjacent trenches 114. The width of the mesa structure is measured at half of a depth of the trench 114.

The semiconductor device 100 illustrated in FIG. 1 represents a vertical gate trench transistor with a field electrode structure, where a vertical inversion channel 138 can be formed at a sidewall of the trench 114 by applying an appropriate potential to the gate electrode structure 124. The field electrode structure 122 allows for a lateral depletion of the drift zone 110 from charge carriers similar to a super-junction structure. Thus, the charge depletion is no longer determined exclusively via the pn-junction between the body region 108 and the drift zone 110, but also via the field electrode structure 122. Thereby, a deeper and higher doped drift zone 110 can be depleted, which improves the trade-off between voltage blocking capability and on-state resistance.

Charge carriers beneath the field electrode structure 122 also have to be dispelled from the semiconductor body 102 when a space charge region is formed during device operation. Since these charge carriers do not lead to a reduction of the on-state resistance or only a minor reduction of the on-state resistance but to an increase of the capacitance and output charge, especially at high drain source voltages, the charge carriers in this region of the semiconductor body 102 have a negative impact on the behavior of the transistor.

Due to the doped region 136 of the semiconductor device 100 the free charge carriers in the semiconductor body 102 beneath the field electrode structure 122 are reduced compared to the free charge carriers in the drift zone 110 between the trenches. Thus, when the doped region 136 is depleted after a first operation period, the doped region 136 may remain depleted when the device is operated with typical frequencies in the range of kHZ to MHz, since the doped region 136 has a behavior similar to a dielectric structure. This leads to a reduced capacitance at the bottom of the trench 114. Thus, when the device is operated with typical frequencies, the amount of carriers beneath the field electrode structure in the semiconductor body that has to be depleted is reduced or is substantially zero after a first operation period, while the on-state resistance remains nearly unchanged The doped region 136 may also have a small inner region that is not depleted during operation of the device. The small inner region preferably has dimensions in a lateral direction parallel to the first surface 104 and in a vertical direction perpendicular to the first surface 104 that are equal or smaller than the thickness d₁ of the first part 128 of the first dielectric structure 126 in a lateral direction parallel to the first surface 104.

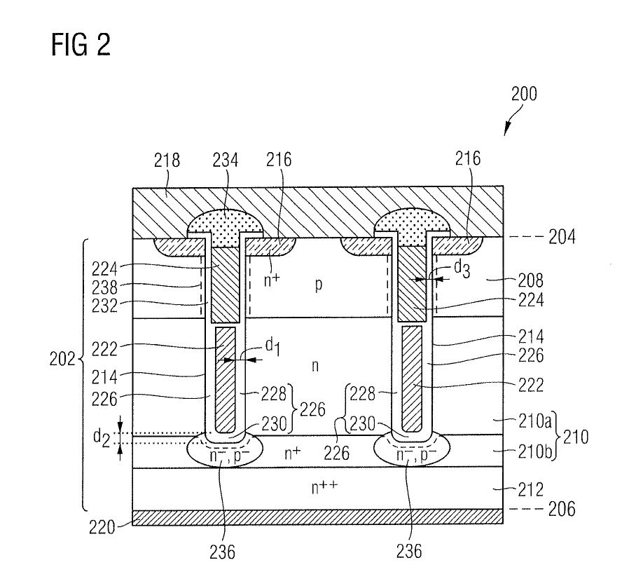

FIG. 2 illustrates a cross-section of a part of a semiconductor device 200 according to another embodiment, more specifically a part of a transistor cell array of the semiconductor device 200. Similar to the semiconductor device 100 illustrated in FIG. 1, the semiconductor device 200 includes a semiconductor body 202 which comprises a p-type body region 208, an n-type drift zone 210 and an n⁺⁺-type drain region 212. A trench 214 extends from a first surface 204 opposite to a second surface 206 into the drift zone 210, wherein a field electrode structure 222 and a gate electrode structure 224 are arranged in the trench 214. An n⁺⁺-type source region 216 adjoins an upper part of the trench 214 and is arranged in the p-type body region 208. The n⁺⁺-type drain region 212 is electrically connected to a drain contact region 220 at the second surface 206 and the source region 216 is electrically connected to a source contact region 218 at the first surface 204.

The n-type drift zone 210 includes a first region 210a having a first doping concentration and a second region 210b having a second doping concentration. The first region 210a is arranged between the first surface 204 and the second region 210b. The first region 210a is also arranged between the second region 210b and the p-type body region 208. The second region 210b has a higher doping concentration than the first region 210a. By way of example, the first region 210a is of n-type and the second region 210b is of n⁺-type. The second region 210b may be a field stop zone or a diffusion tail of a highly doped substrate. For details on further elements illustrated in FIG. 2, reference is drawn to corresponding elements in FIG. 1. The first and second regions 210a, 210b may have a constant doping concentration or, for example, have a gradient of doping concentration along a vertical direction perpendicular to the first surface 204.

The semiconductor device 200 illustrated in FIG. 2 allows for similar benefits described above with regard to the embodiment illustrated in FIG. 1.

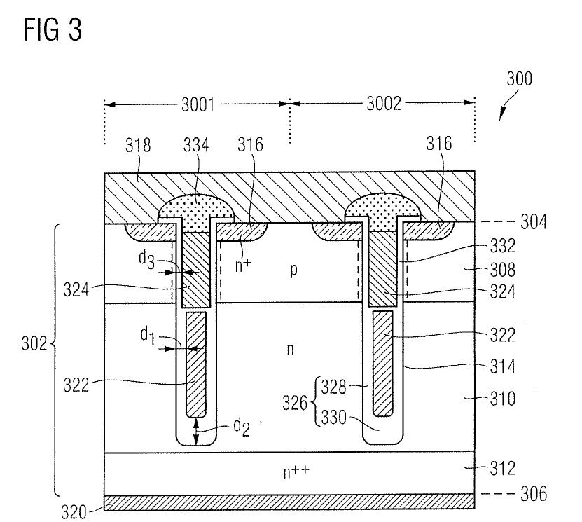

FIG. 3 illustrates a cross-section of a part of a semiconductor device 300 according to another embodiment, more specifically, a part of a transistor cell array of the semiconductor device 300. Similar to the semiconductor devices 100, 200 illustrated in FIGS. 1 and 2, the semiconductor device 300 includes a semiconductor body 302 which comprises a p-type body region 308, an n-type drift zone 310 and an n⁺⁺-type drain region 312. The semiconductor device 300 further comprises a trench 314 which extends from a first surface 304 opposite to a second surface 306 into the drift zone 310, a field electrode structure 322 and a gate electrode structure 324 arranged in the trench 314, an n⁺⁺-type source region 316 which adjoins an upper part of the trench 314, a drain contact region 320 electrically connected to the drain region 312, a source contact region 318 electrically connected to the source region 316 and an isolating structure 334 electrically isolating the gate electrode structure 324 from the source contact region 318.

Similar to the embodiments of FIGS. 1 and 2, a first dielectric structure 326 comprises a first part 328 between each one of opposite sidewalls of the trench 314 and the field electrode structure 322 and a second part 330 between a bottom side of the trench 314 and the field electrode structure 322, wherein the first part 328 and the second part 330 constitute a field dielectric. The first dielectric structure 326 further includes a third part 332 between each of the sidewalls of the trench 314 and the gate electrode structure 324, which constitutes a gate dielectric. The first part 328 has a first thickness d₁ in a direction parallel to the first surface 304 and the second part 330 has a second thickness d₂ in a direction perpendicular to the first surface 304. In this embodiment, the second thickness d₂ is greater than the first thickness d₁, for example the second thickness d₂ is at least twice the first thickness d₁ or may even be larger. The gate dielectric has a third thickness d₃ in the direction parallel to the first and second surfaces 304, 306. In this embodiment, the third thickness d₃ of the third part 332 is smaller than the first thickness d₁ of the first part 328.

In an embodiment, the second part 330 of the first dielectric structure 326 between the bottom wall of the trench 314 and the field electrode structure 322 is formed by a thick oxide, i.e. a field oxide that is thicker in the second part 330 than in the first part 328. The thick oxide may be formed by a high density plasma (HDP) CVD (chemical vapor deposition) process, where the deposition process is interspersed with a sputtering etch process, for example. Sputtered material is preferably deposited at the bottom of the trench 314, resulting in a greater thickness at the bottom of the trench 314 than at the sidewalls of the trench 314. In another embodiment, the second part 330 of the first dielectric structure 326 is a stacked structure of two or more different electrically insulating materials. In an embodiment, the stacked structure may comprise oxide and nitride. In a further embodiment, the stacked structure may comprise insulating materials with a lower dielectric constant than that of oxide, i.e. low-k dielectric materials and/or cavities formed between layers of electrically insulating materials. The stacked structure may comprise layers of low-k dielectric materials and oxide layers.

The increased thickness of the first dielectric structure 326 at the bottom of the trench 314 in which the field electrode structure is located allows for a reduction of the capacitance at the bottom of the trench due to an increased distance between the semiconductor body and the field electrode, while the on-state resistance remains nearly unchanged.

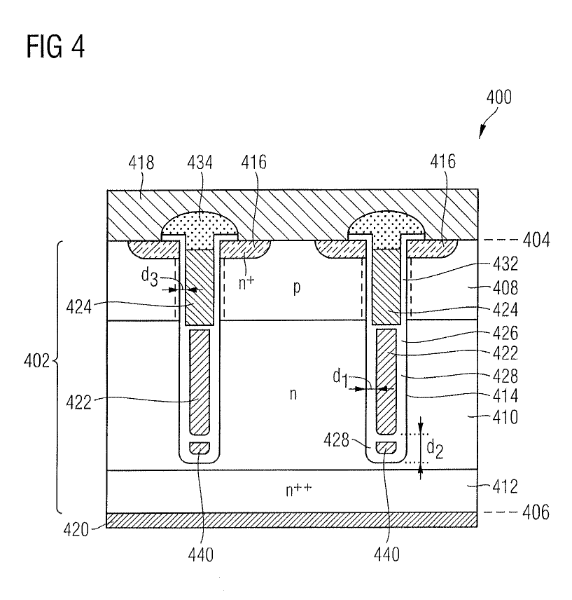

FIG. 4 illustrates a cross-section of a part of a semiconductor device 400 according to another embodiment, more specifically, a part of a transistor cell array of the semiconductor device 400. Similar to the semiconductor device 300 illustrated in FIG. 3, the semiconductor device 400 includes a semiconductor body 402 which comprises a p-type body region 408, an n-type drift zone 410 and an n⁺⁺-type drain region 412. The semiconductor device 400 further comprises a trench 414 which extends from a first surface 404 opposite to a second surface 406 into the drift zone 419, a field electrode structure 422 and a gate electrode structure 424 arranged in the trench 414, an n⁺⁺-type source region 416 which adjoins an upper part of the trench 414, a drain contact region 420 electrically connected with the drain region 412, a source contact region 418 electrically connected with the source region 416 and an isolating structure 434 electrically isolating the gate electrode structure 424 from the source contact region 418. The semiconductor device 400 further comprises a first dielectric structure 426 having a first part 428 between each one of opposite sidewalls of the trench 414 and the field electrode structure 422, a second part 430 between the bottom side of the trench 416 and the field electrode structure 422 and a third part 432 between each one of opposite sidewalls of the trench 414 and a gate electrode structure 424.

The semiconductor device further comprises further a structure 440 in the trench 414 between the field electrode structure 422 and a bottom side of the trench 414. The structure 440 is surrounded by the first dielectric structure 426. The structure 440 is one of a dielectric material other than the first dielectric structure 426, a void and a conductive material, for example.

For details on further elements illustrated in FIG. 4, reference is drawn to corresponding elements in FIG. 3.

The semiconductor device 400 illustrated in FIG. 4 allows for similar benefits described above with regard to the embodiment illustrated in FIG. 3.

The embodiments illustrated in FIGS. 1 and 2 may be combined in any way with the embodiments illustrated in FIGS. 3 and 4.

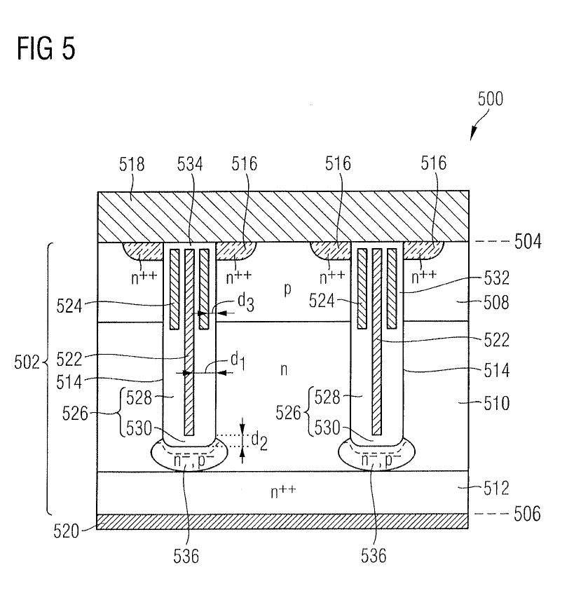

FIG. 5 illustrates a cross-section of a part of a semiconductor device 500 according to another embodiment, more specifically, a part of a transistor cell array of the semiconductor device 500. The semiconductor device 500 includes a semiconductor body 502 which comprises a p-type body region 508, an n-type drift zone 510 and an n⁺⁺-type drain region 512. The semiconductor device 500 further comprises a trench 514 which extends from a first surface 504 opposite to a second surface 506 into the drift zone 510, an n⁺⁺-type source region 516 which adjoins an upper part of the trench 514, a drain contact region 520 electrically connected with the drain region 512, a source contact region 518 electrically connected with the source region 516.

In this embodiment, a gate electrode structure 524 and a field electrode structure 522 are arranged in the same trench 514 adjacent to each other. The field electrode structure 522 extends deeper into the trench 514 than the gate electrode structure 524. The gate electrode structure 524 and the field electrode structure 522 may be arranged such that an upper part of the field electrode structure 522 is arranged between two gate electrodes 524 in the same trench 514. The gate electrode structure 524 may also surround the field electrode structure 522 in the upper part of the trench 514 so as to enclose the field electrode structure 522. An isolating structure 534 electrically isolates the gate electrode structure 524 and the field electrode structure 522 from the source contact region 518. The semiconductor device 500 further comprises a first dielectric structure 526 electrically isolating the gate electrode structure 524 and the field electrode structure 522 from the semiconductor body 502 and from each other. The first dielectric structure 526 has a first part 528 between each one of opposite sidewalls of the trench 514 and the field electrode structure 522 in a lower part of the trench 514, a second part 530 between the bottom side of the trench 514 and the field electrode structure 522, as well as a third part 532 between each one of opposite sidewalls of the trench 514 and the gate electrode structure 524. As is illustrated in FIG. 5, the first part 528 has a first thickness d₁ in a direction lateral to the first surface 504 which is greater than a third thickness d₃ of the third part 532 in the direction lateral to the first surface 504.

Similar to the semiconductor devices 100, 200 of FIGS. 1 and 2, the semiconductor device 500 of FIG. 5 includes a doped region 536 surrounded by the drift zone 510 and lining the bottom side of the trench 514. The doped region 536 does not extend up to that part of the sidewall of the trench 514 where the third part 532 of the first dielectric structure 526 is located. Thus, the sidewalls of the trench 514 are in contact with the drift zone 510 and the body region 508. In an embodiment, the doped region 536 is n-type. More specifically, the doped region 536 is n⁻-type and has a lower doping concentration than the drift zone 510 between adjacent trenches 514. In another embodiment, the doped region 536 is p-type, more specifically p⁻-type. Changing of the doping type and level may be achieved by introducing acceptors into the region of the semiconductor body 502 which is located beneath the trench 514, wherein the amount of introduced acceptors defines whether the concentration of doping is merely lowered with respect to the drift zone 510 or whether counter-doping of the doping type of the drift zone 510 occurs, i.e. the conductivity type of the drift zone 510 is reversed by the introduced acceptors.

According to an embodiment, the doped region 536 has a width in a lateral direction parallel to the first surface 504 which is in a range of 0.2 μm to 2 μm. According to another embodiment, the doped region 536 has a width in the lateral direction which is the width of the mesa structure in the lateral direction parallel to the first surface 504 or less, wherein the mesa structure corresponds to the region of the semiconductor body 502 that is located between adjacent trenches 514.

In another embodiment, the semiconductor device 500 of FIG. 5 may have in addition to the doped region 536 or instead of the doped region 536 a second part 530 of the first dielectric structure 526 that has a second thickness d₂ in a direction perpendicular to the first surface 504 that is greater than the first thickness d₁ of the first part 528 in the lateral direction. Similar to the embodiment illustrated in FIG. 3, the thick second part of the first dielectric structure 526 may be a thick oxide and/or a stacked structure of electrically insulating materials.

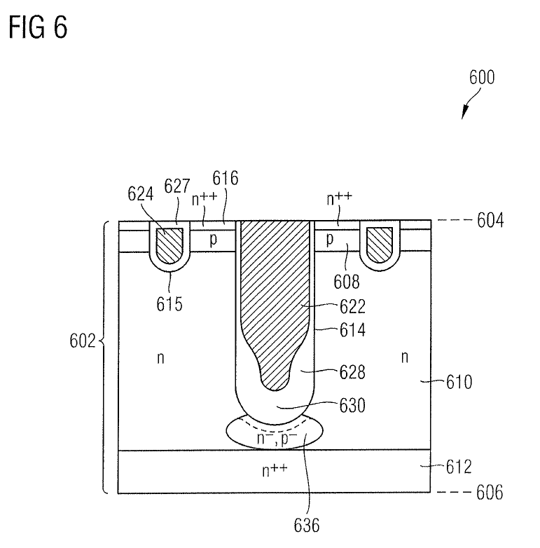

FIG. 6 illustrates a cross-section of a part of a semiconductor device 600 according to another embodiment. The semiconductor device 600 includes a semiconductor body 602 which comprises a p-type body region 608, an n-type drift zone 610 and an n⁺⁺-type drain region 612. The semiconductor device 600 further comprises a first trench 614 which extends from a first surface 604 opposite to a second surface 606 into the drift zone 610, a second trench 615 which extends from the first surface 604 into the drift zone 610 and an n⁺⁺-type source region 616 which adjoins an upper part of the first and second trenches 614, 615. The first trench 614 comprises a field electrode structure 622 that is electrically isolated from the semiconductor body 602 by a first dielectric structure 626. The semiconductor device 600 further comprises a second trench 615 including a gate electrode structure 624. Thus, the gate electrode structure 624 and the field electrode structure 622 are arranged in separate trenches 614, 615. The gate electrode structure 624 is electrically isolated from the semiconductor body 602 by a second dielectric structure 627. The field electrode structure 622 may be shaped as a needle at a bottom part of the first trench 614.

Similar to the semiconductor devices 100, 200 of FIGS. 1 and 2, a doped region 636 is surrounded by the drift zone 610 lining the bottom side of the first trench 614. In an embodiment, the doped region 636 is n-type. More specifically, the doped region 636 is n⁻-type and has a lower doping concentration than the drift zone 610 surrounding the doped region. In another embodiment, the doped region 636 is p-type, more specifically p⁻-type.

The semiconductor device 600 may further comprise in addition or instead of the doped region 636 a second part 630 of the first dielectric structure 526 similar to the second part 330 of the embodiment illustrated in FIG. 3.

The semiconductor devices 500, 600 illustrated in FIGS. 5, 6 allow for similar benefits as described above with regard to the embodiments illustrated in FIGS. 1 to 4.

The semiconductor devices illustrated in FIGS. 1 to 6 may be implemented in a switched-mode power supply device, more specifically in a resonant switched-mode power supply device such as a resonant half bridge (LLC) converter. The semiconductor devices may act as secondary side rectifying elements in switched-mode power supply devices, for example.

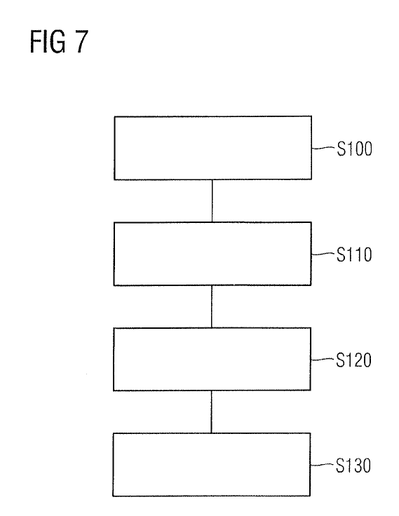

FIG. 7 illustrates a schematic process chart of a method of manufacturing a semiconductor device such as the semiconductor device 100 or 200 illustrated in FIGS. 1 and 2. The semiconductor device includes a plurality of transistor cells, wherein forming each transistor cell comprises the process features described below:

Process feature S100 includes forming a trench extending into a drift zone of a semiconductor body from a first surface, the drift zone being of a first conductivity type.

Process feature S110 includes forming a doped region surrounded by the drift zone and lining a bottom side of the trench, the doped region being one of a first conductivity type having a doping concentration lower than the drift zone, and a second conductivity type complementary to the first conductivity type.

Process feature S120 includes forming a first dielectric structure and a field electrode structure in the trench.

Process feature S130 includes forming a gate electrode structure.

As an example, the trench may be formed by anisotropic etching, e.g. by dry etching. The semiconductor body may be a semiconductor wafer, e.g. a silicon wafer, including none, one or a plurality of semiconductor layers, e.g. epitaxial semiconductor layers, thereon.

According to an embodiment, forming the doped region comprises introducing dopants through the trench into the drift zone after forming the first dielectric structure.

According to another embodiment, forming the first dielectric structure comprises forming a first part at sidewalls of the trench, and forming a second part at a bottom side of the trench, the first part having a first thickness d₁ in a direction parallel to the first surface and the second part having a second thickness d₂ in a direction perpendicular to the first surface, the first thickness being smaller than the second thickness.

According to another embodiment, forming the first dielectric structure includes high density plasma processing.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1-24. (canceled)

25. A semiconductor device, comprising a plurality of transistor cells, each transistor cell of the plurality of transistor cells comprising:
a trench extending into a drift zone of a semiconductor body from a first surface, the drift zone being of a first conductivity type;
a gate electrode structure;
a field electrode structure and a first dielectric structure in the trench;
a doped region surrounded by the drift zone and lining a bottom side of the trench, wherein the doped region is of a second conductivity type different from the first conductivity type and has a doping concentration lower than the drift zone, and wherein the first dielectric structure includes a field dielectric part between each one of opposite sidewalls of the trench and the field electrode structure, and a gate dielectric part between each one of opposite sidewalls of the trench and the gate electrode structure, wherein a thickness of the gate dielectric part is smaller than a thickness of the field dielectric part.

26. The semiconductor device of claim 25, wherein the doped region abuts the bottom side of the trench.

27. The semiconductor device of claim 25, wherein a width of the doped region along a direction parallel to the first surface is in a range of 0.2 μm to 2 μm.

28. The semiconductor device of claim 25, wherein the drift zone comprises a first region with a first doping concentration and a second region with a second doping concentration higher than the first doping concentration, the first region being arranged between the second region and the first surface, and wherein the doped region is arranged in the second region of the drift zone.

29. The semiconductor device of claim 25, wherein the first dielectric structure in the trench further includes a bottom part between a bottom side of the trench and the field electrode structure, wherein the field dielectric part has a first thickness in a direction parallel to the first surface and the bottom part has a second thickness in a direction perpendicular to the first surface, the first thickness being smaller than the second thickness.

30. The semiconductor device of claim 5, wherein the second thickness is greater than two times the first thickness.

31. The semiconductor device of claim 5, wherein the second part of the first dielectric structure is a stacked structure of a plurality of layers of electrically insulating materials.

32. The semiconductor device of claim 25, wherein the gate electrode structure is in the trench, and the field electrode structure is arranged between the gate electrode structure and a bottom side of the trench.

33. The semiconductor device of claim 25, wherein the gate electrode structure is in the trench, the gate electrode structure being arranged adjacent to the field electrode structure in a direction parallel to the first surface.

34. The semiconductor device of claim 33, wherein the gate electrode structure comprises first and second sub gate electrodes opposite to each other, the field electrode structure being at least partly arranged between the first and second sub gate electrodes.

35. The semiconductor device of claim 25, wherein the field electrode structure is arranged in a first trench and the gate electrode structure is arranged in a second trench adjacent to the first trench, the first and second trenches extending into the drift zone of the semiconductor body, a source region and a body region being arranged between the first and second trenches.

36. The semiconductor device of claim 25, wherein a vertical distance between a bottom side of the trench to one of a field stop zone and a highly doped drain region is less than a lateral distance between trenches of adjacent two of the plurality of transistor cells.

37. A semiconductor device, comprising a plurality of transistor cells, each transistor cell comprising:
a trench extending into a drift zone of a semiconductor body from a first surface, the drift zone being of a first conductivity type;
a gate electrode structure;
a field electrode structure and a first dielectric structure in the trench; and
wherein the first dielectric structure in the trench includes a first part between each one of opposite sidewalls of the trench and the field electrode structure, a second part between a bottom side of the trench and the field electrode structure, and a third part between each one of opposite sidewalls of the trench and the gate electrode structure, the first part having a first thickness in a direction parallel to the first surface, the second part having a second thickness in a direction perpendicular to the first surface, the third part having a third thickness in a direction parallel to the first surface, the first thickness being smaller than the second thickness, and the third thickness being smaller than the first thickness.

38. The semiconductor device of claim 37, wherein the second part of the first dielectric structure includes a stack of electrically insulating materials.

39. The semiconductor device of claim 37, wherein the second thickness is greater than two times the first thickness.

40. The semiconductor device of claim 37, wherein a vertical distance between a bottom side of the trench to one of a field stop zone and a highly doped drain region is less than a lateral distance between trenches of adjacent two of the plurality of transistor cells.

41. The semiconductor device of claim 37, further comprising a doped region surrounded by the drift zone and lining a bottom side of the trench, wherein the doped region is of a second conductivity type different from the first conductivity type and has a doping concentration lower than the drift zone.

42. The semiconductor device of claim 37, further comprising a doped region surrounded by the drift zone and lining a bottom side of the trench, wherein the doped region is of a second conductivity type that is the same as the first conductivity type and has a doping concentration lower than the drift zone.

43. A switched-mode power supply device, comprising the semiconductor device of claim 25.

44. The switched-mode power supply device of claim 43, wherein the switched-mode power supply device is a resonant switched-mode power supply device.
